(19) United States
(12) Patent Application Publication
(10) Pub. No.: US 2025/0038664 A1
(43) Pub. Date: Jan. 30, 2025

(54) DIGITAL CONTROLLER

(71) Applicant: Renesas Design (UK) Limited, Bourne End (GB)

(72) Inventors: Thomas MAYERWIESER, Edinburgh (GB); Codrin HORA, Edinburgh (GB); Guillaume De Cremoux, Edinburgh (GB)

(73) Assignee: Renesas Design (UK) Limited, Bourne End (GB)

(21) Appl. No.: 18/361,345

(22) Filed: Jul. 28, 2023

(51) Int. Cl. H02M 3/157; H02M 3/155; H02M 3/158

(52) U.S. Cl. CPC H02M 3/157; H02M 3/1552; H02M 3/1582

(57) ABSTRACT

A digital controller for a switching converter configured to receive an input voltage at an input voltage node and to generate an output voltage at an output voltage node, the switching converter comprising one or more power switches and an energy storage element, the digital controller comprising a pulse width modulation control circuit configured to receive the output voltage and to generate a PWM control signal to control the switching operation of the one or more power switches, and switching circuitry configured to couple the pulse width modulation control circuit to the input voltage node during a first phase, and couple the pulse width modulation control circuit to a supply voltage node during a second phase, the supply voltage node being at a supply voltage.

The present disclosure relates to a digital controller. In particular, the present disclosure relates to a digital controller for a switching converter.

### BACKGROUND

FIG. 1(a) is a schematic of a digital buck converter 100 with analog to digital converters (ADC) 102, 104, 106 and a controller 108. The buck converter 100 comprises switches 110, 112, an inductor 114 and a capacitor 116. During operation, the switching converter receives an input voltage VIN and generates and output voltage VOUT.

While the power stage and passive components (the inductor 114 and the capacitor 116) remain the same as for an analog buck converter, the ADC 102 converts the output voltage VOUT into a digital number. Optionally, the inductor current IL of the inductor 114, and the input voltage VIN can also be converted from analog to digital, depending on the digital control method.

We distinguish:
The switching frequency (FSW) of the buck converter 100, for example 2 MHz. FSW is equal to 1/TSW, where TSW is the switching period of the buck converter 100. FSW is the frequency of the power stage.
The processing frequency of the digital controller 108 (FS), for example about 100 MHz. FS is equal to 1/TS, where TS is the processing period of the controller 108. FS can also optionally be the sampling frequency of ADC 102.

The controller 108 may be operable in different modes depending on conditions relating to the load. The load is a component that consumes electrical power, as provided by the buck converter 100 when coupled to the load. The load may draw a load current from the buck converter 100, with a “high load” referring to a higher load current draw than during a “low load” or a “light load”.

At a high load, the digital controller provides pulse width modulation (PWM) control, with pulse frequency modulation (PFM) control being provided at light loads.

Digital loops at high loads operate in PWM to meet the following requirements:
Higher accuracy and low ripple as needed for VOUT, when compared to PFM.
PWM provides a constant frequency.
Transient load response: the PWM can react faster than PFM.

At light load, the digital buck converter 100 operates in PFM, where the requirements are less stringent. However, the controller 108 is required to consume less power.

FIG. 1(b) is a schematic of the digital buck converter 100 and the controller 108 for providing PWM and PFM control. The buck converter 100 comprises switching circuitry 109. The controller 108 comprises PWM control circuitry 118 and PFM control circuitry 120. The operation of the circuit components is synchronized using a clock signal FS. The system includes a finite state machine (FSM) 121 to manage the control of the system, and a decoupling capacitor 123. The FSM 121 is always on. The PWM control circuitry 118 and the PFM control circuitry 120 receive a supply voltage VDIG from a low dropout regulator (LDO) 121, which supplies power to the respective control sub-circuits.

The PWM control circuitry 118 comprises an ADC 122, a DIGLOOP circuit 124, and a DIGPWM circuit 126. The PWM control circuitry 118 is for high performance PWM control and is disabled at light loads.

The PFM control circuitry 120 comprises an analog comparator 128 and a DIGPFM circuit 130. The analog comparator 128 detects the output voltage VOUT level in during the PFM mode of operation, and the DIGPFM circuit 130 controls the switching operation of the buck converter 100 to “top up” the input voltage VOUT whenever it falls. Note that the DIGPFM circuit 130 may use the clock signal FS, another slower clock, or even no clock at all, to reduce its power consumption.

The PWM control circuitry 118 increases power consumption and degrades efficiency. For example, if the load current IOUT is in the range 100 uA to 1 mA, the typical consumption of the PWM control circuitry, whilst the clock signal FS is switching, is 10 mA for a total number of 100,000 transistor gates. Therefore, the controller 108 consumes 100 time more power than the load on the output voltage VOUT.

### SUMMARY

It is desirable to reduce the power consumption and improve the efficiency of a controller for a switching converter that uses a pulse width modulation control scheme.

According to a first aspect of the disclosure there is provided a digital controller for a switching converter configured to receive an input voltage at an input voltage node and to generate an output voltage at an output voltage node, the switching converter comprising one or more power switches and an energy storage element, the digital controller comprising a pulse width modulation control circuit configured to receive the output voltage and to generate a PWM control signal to control the switching operation of the one or more power switches, and switching circuitry configured to couple the pulse width modulation control circuit to the input voltage node during a first phase, and couple the pulse width modulation control circuit to a supply voltage node during a second phase, the supply voltage node being at a supply voltage.

Optionally, the switching converter is a buck converter, a boost converter, or a buck-boost converter.

Optionally, the energy storage element is an inductor.

Optionally, the one or more power switches comprises a first power switch and a second power switch.

Optionally, the pulse width modulation control circuit comprises an analog to digital converter coupled to the output voltage node and configured to digitize the output voltage to provide a digital representation of the output voltage.

Optionally, the pulse width modulation control circuit comprises a digital loop circuit.

Optionally, the pulse width modulation control circuit comprises a digital PWM circuit.

Optionally, the first phase precedes the second phase.

Optionally, the first phase is a charging phase and the second phase is a holding phase.

Optionally, during the first phase, the supply voltage node is decoupled from the pulse width modulation control circuit and during the second phase the input voltage node is decoupled from the pulse width modulation control circuit.

Optionally, the switching circuitry comprises one or more first phase switches for coupling the pulse width modulation control circuit to the input voltage node during the first phase and one or more second phase switches for coupling the pulse width modulation control circuit to the supply voltage node during the second phase.

Optionally, the first phase precedes the second phase.

Optionally, the first phase is a charging phase and the second phase is a holding phase.

Optionally, during the first phase, the one or more second phase switches are open such that the supply voltage node is decoupled from the pulse width modulation control circuit and during the second phase, the one or more first phase switches are open such that the input voltage node is decoupled from the pulse width modulation control circuit.

Optionally, the pulse width modulation control circuit comprises an analog to digital converter coupled to the output voltage node and configured to digitize the output voltage to provide a digital representation of the output voltage, the one or more first phase switches comprises a first switch for coupling the analog to digital converter to the input voltage node during the first phase, and the one or more second phase switches comprises a second switch for coupling the analog to digital converter to the supply voltage node during the second phase.

Optionally, the pulse width modulation control circuit comprises a digital loop circuit, the one or more first phase switches comprises a third switch for coupling the digital loop circuit to the input voltage node during the first phase, and the one or more second phase switches comprises a fourth switch for coupling the digital loop circuit to the supply voltage node during the second phase.

Optionally, the pulse width modulation control circuit comprises a digital PWM circuit, the one or more first phase switches comprises a fifth switch for coupling the digital PWM circuit to the input voltage node during the first phase, and the one or more second phase switches comprises a sixth switch for coupling the digital PWM circuit to the supply voltage node during the second phase.

Optionally the digital controller comprises a circuit component, the one or more first phase switches comprises a first switch comprising a first transistor for coupling the circuit component to the input voltage node during the first phase, and the one or more second phase switches comprises a second switch comprising a second transistor for coupling the circuit component to the supply voltage node during the second phase, a third transistor comprising a gate coupled to a gate of the first transistor, a fourth transistor coupled in series with the third transistor, a comparator comprising a first comparator input terminal coupled to the first transistor and the second transistor, a second comparator input terminal coupled to the supply voltage node, and a comparator output terminal for outputting a charging signal, an OR gate comprising a first OR gate input terminal coupled to a turn-off signal, a second OR gate input terminal coupled to the comparator output terminal for receiving the charging signal, an OR gate output terminal coupled to a gate of the second transistor, an AND gate comprising a first AND gate input terminal coupled to the comparator output terminal for receiving the charging signal, a second AND gate input terminal coupled to a turn-on signal, and an AND gate output terminal coupled to a gate of the fourth transistor.

Optionally, the circuit component is one of an analog to digital converter coupled to the output voltage node and configured to digitize the output voltage to provide a digital representation of the output voltage, a digital loop circuit, and a digital PWM circuit.

Optionally, the pulse width modulation control circuit is configured to control the switching operation of the one or more switches during a first mode of operation.

Optionally, the digital controller comprises additional control circuitry configured to control the switching operation of the one or more switches during a second mode of operation.

Optionally, the additional control circuitry comprises a pulse frequency modulation control circuit.

Optionally, the first mode of operation is a high load mode of operation and the second mode of operation is a low load mode of operation.

Optionally, the digital controller comprises a voltage regulator or a power rail for providing the supply voltage at the supply voltage node.

Optionally, the voltage regulator comprises a low dropout regulator or a buck converter.

Optionally, the voltage regulator comprises a low dropout regulator configured to receive the input voltage and to provide the supply voltage at the supply voltage node.

According to a second aspect of the disclosure there is provided a method of controlling a switching converter configured to receive an input voltage at an input voltage node and to generate an output voltage at an output voltage node, the switching converter comprising one or more power switches and an energy storage element, the method comprising receiving the output voltage at a pulse width modulation control circuit, generating a PWM control signal to control the switching operation of the one or more power switches using the pulse width modulation control circuit, coupling the pulse width modulation control circuit to the input voltage node during a first phase, and coupling the pulse width modulation control circuit to a supply voltage node during a second phase, the supply voltage node being at a supply voltage.

It will be appreciated that the method of the second aspect may include features set out in the first aspect and can incorporate other features as described herein.

### BRIEF DESCRIPTION OF THE DRAWINGS

The disclosure is described in further detail below by way of example and with reference to the accompanying drawings in which:

FIG. 1(a) is a schematic of a digital buck converter, FIG. 1(b) is a schematic of the digital buck converter of FIG. 1(a) and a controller for providing PWM and PFM control;

FIG. 2 is a schematic of the system of FIG. 1(b) configured to use a known method of power gating;

FIG. 3 is a schematic of a digital controller for a switching converter in accordance with a first embodiment of the present disclosure;

FIG. 4(a) is a schematic of a digital controller in accordance with a second embodiment of the present disclosure, FIG. 4(b) is a schematic of the digital controller of FIG. 4(a), with a specific embodiment of switching circuitry, in accordance with a third embodiment of the present disclosure;

FIG. 5(a) is a schematic of a digital controller and a switching converter, in accordance with a fourth embodiment of the present disclosure, FIG. 5(b) is a schematic of a digital controller and a switching converter, in accordance with a fifth embodiment of the present disclosure;

FIG. 6(a) is a schematic of a portion of a digital controller as may be implemented in a specific embodiment of one of the digital controllers, FIG. 6(b) is a graph showing example waveforms as they vary with time for a practical implementation of the digital controller of FIG. 6(a);

FIG. 7(a) is a schematic of a digital controller in accordance with a sixth embodiment of the present disclosure, FIG. 7(b) is a graph showing simulation results of the system presented in FIG. 7(a); and

FIG. 8 is a schematic of a specific embodiment of a PWM control circuit.

### DETAILED DESCRIPTION

It is desirable to reduce the power consumption of the blocks DIGLOOP 124 and DIGPWM 126. The ADC 122 may be switched off when not in use such that its power consumption is reduced to zero.

An immediate method is to gate the clock signal FS where the total supply current IDD budget may be as follows:

| Block | IDD (whilst FS is not switching) |
|---|---|
| ACOMP | 10 μA |
| DIGLOOP + DIGPWM | 20 μA |
| DIGPFM + FSM | 5 μA |

The residual 20 μA consumption for DIGLOOP+DIGPWM is due to digital leakage (also called subthreshold current).

If the load current IOUT is 100 μA (i.e. output power POUT=100 μW at the output voltage VOUT=1V), we end up for input power PIN as:

$$PIN = VIN \times ( Total\_IDD + ( IOUT \times VOUT ) / VIN ) \qquad ( 1 )$$

where Total_IDD is the total supply current IDD, and the other symbols have their meanings as previously described.

$$PIN = 3.6 V \times ( 35 μA + ( 100 μA \times 1 V ) / 3.6 V ) = 226 μW \qquad ( 2 )$$

The POUT/PIN efficiency is 44% and this 20 μA leakage has contributed a 72 μW of loss. Without this leakage, the efficiency would become 66%.

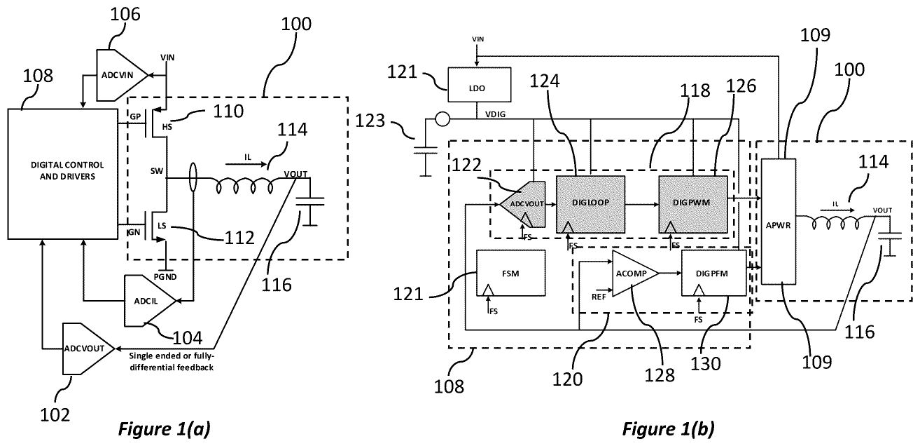

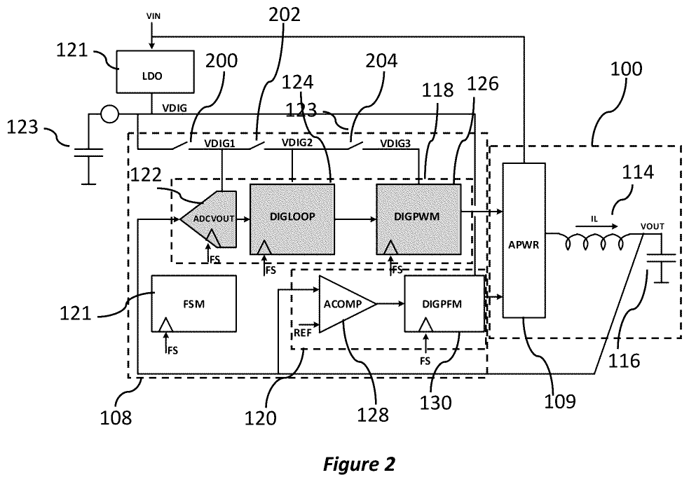

FIG. 2 is a schematic of the system of FIG. 1(b) configured to use the known method of power gating. The controller 108 further comprises switches 200, 202, 204.

The PWM control circuitry 118 can be disconnected from VDIG so that leakage is suppressed. A daisy chain of switches 200, 202, 204 to create the power-gated supplies VDIG1, VDIG2, VDIG3 is created to control the in-rush current taken from VDIG. VDIG1, VDIG2, VDIG3 denote voltage rails.

However, applying this method in the context of the buck converter 100 results in the following shortcomings:
The daisy chain wake-up (power up VDIG1, VDIG2, VDIG3) is typically 100 ns: it cannot be used for a buck converter 100 that needs to wake up its PWM control circuitry 118 in 20 ns in case of a sudden load transient on the output voltage VOUT.
There is residual kick-back on VDIG due to the daisy-chain 200, 202, 204. If the buck converter 100 is instantiated in a power management integrated circuit (PMIC) with multiple buck converters 100, the wake-up of the supply voltage VDIG may be further slowed down.
Care must be taken in the top-cell PMIC layout: the metal tracks to serve VDIG1, VDIG2, VDIG3 must be over-sized to support the large in-rush current to charge these nodes compared to their normal consumption. For example: if the total equivalent capacitance on VDIG1 is 100 pF (due to all the digital gates) and a wake-up time of 20 ns is preferred at 1V supply, the in-rush current is: I_in-rush=100 pF×(1V/20 ns)=5 mA, while the normal consumption of this block could have been e.g. 2.5 mA: the power connection to VDIG1 must be twice larger just for being able to charge it in 20 ns.

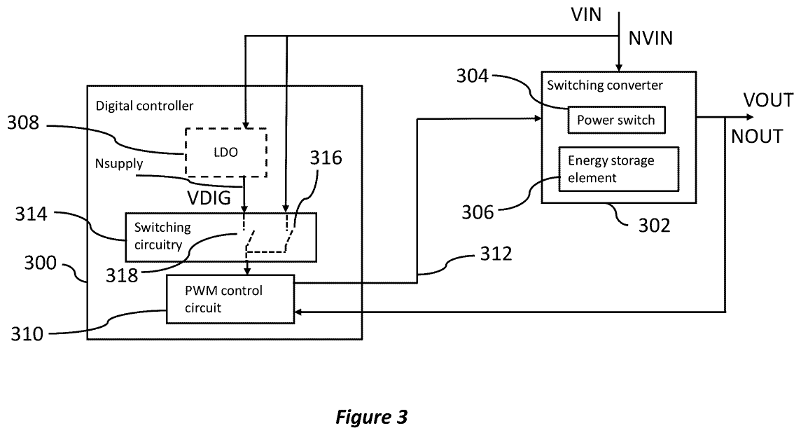

FIG. 3 is a schematic of a digital controller 300 for a switching converter 302, in accordance with a first embodiment of the present disclosure. The switching converter 302 receives an input voltage VIN at an input voltage node NVIN and generates an output voltage VOUT at an output voltage node NOUT. The switching converter 302 comprises one or more power switches 304 and an energy storage element 306.

The switching converter 302 may, for example, be a buck converter, a boost converter, or a buck-boost converter. The energy storage element 306 may be an inductor. The switching converter 302 may comprise a first power switch and a second power switch (as is the case for the buck converter of FIG. 1(a)).

The digital controller 300 further comprises a pulse width modulation (PWM) control circuit 310 that is configured to receive the output voltage VOUT and to generate a PWM control signal 312 that is used to control the switching operation of the power switches 304. It will be appreciated that for the purpose of the illustration there is shown a single power switch. Specific embodiments may include one or more power switches in accordance with the understanding of the skilled person.

The PWM control circuit 310 may comprise a gate driver such that the PWM control signal 312 in a high state is used to enable the high-side switches, and the PWM control signal 312 in a low state is used to enable low-side switches.

The PWM control signal 312 may be generated as follows. The digitized output voltage is compared to a reference voltage (target or “desired” voltage setting: synthesized or configurable output voltage setting) and based on the result the PWM signal 312 is generated and used to control the switches which are turned on or off in order to regulate VOUT to the desired value.

The digital controller 300 further comprises switching circuitry 314. During operation, the switching circuitry 314 couples the PWM circuit 310 to the input voltage node NVIN during a first phase of operation. During operation, the switching circuitry 314 couples the PWM control circuit 310 to a supply voltage node Nsupply during a second phase of operation. The supply voltage node is at a supply voltage VDIG.

In a specific embodiment, the digital controller 300 may comprise a low dropout regulator LDO 308 that is configured to receive the input voltage VIN and provide the supply voltage VDIG at the supply voltage node Nsupply.

The following description and embodiments will include the LDO 308 for providing the supply voltage VDIG. It will be appreciated that further embodiments may use alternative methods and/or components for providing the supply voltage VDIG. For example, the supply voltage VDIG may be provided by a different type of voltage regulator, such as a buck converter; or it may be provided by a power rail.

Therefore, during the first phase, the PWM control circuit 310 has its power supplied from the input voltage VIN; and during the second phase, the PWM control circuit 310 has its power supplied from the supply voltage VDIG.

The first phase may precede the second phase. For example, the first phase may be a start-up phase, when the digital controller 300 initially activates the PWM control mode. When a certain condition is reached, the digital controller 300 may then switch to a second phase relating to normal operation during the PWM control mode, when the PWM control circuit 310 is powered using the power supply VDIG. The first phase may be a charging phase, and the second phase may be a holding phase.

During the first phase, the supply voltage node Nsupply may be decoupled from the PWM control circuit 310. During the second phase the input voltage node NVIN may be decoupled from the PWM control circuit 310.

The switching circuitry 314 may comprise one or more first phase switches comprising a first switch 316 for coupling the PWM control circuit 310 to the input voltage node NVIN during the first phase and one or more second phase switches comprising a second switch 318 for coupling the PWM control circuit 310 to the supply voltage node Nsupply during the second phase.

During the first phase, the second switch 318 may be open such that the supply voltage node Nsupply is decoupled from the PWM control circuit 310. During the second phase the first switch 316 may be open such that the input voltage node NVINV is decoupled from the PWM control circuit 310.

By having a first phase, where power is supplied by the input voltage VIN, instead of the supply voltage VDIG, the in-rush current is taken from the input voltage VIN supply (typically 3.6V), which can support kick-back effects and from which much more voltage drop can be affordable (for example, from 3.6V to the 1.0V voltage rail). This, therefore, suppresses the current intake from the supply voltage VDIG, and resolves the shortcomings as presented in relation to the controller 108 as described in relation to FIG. 2.

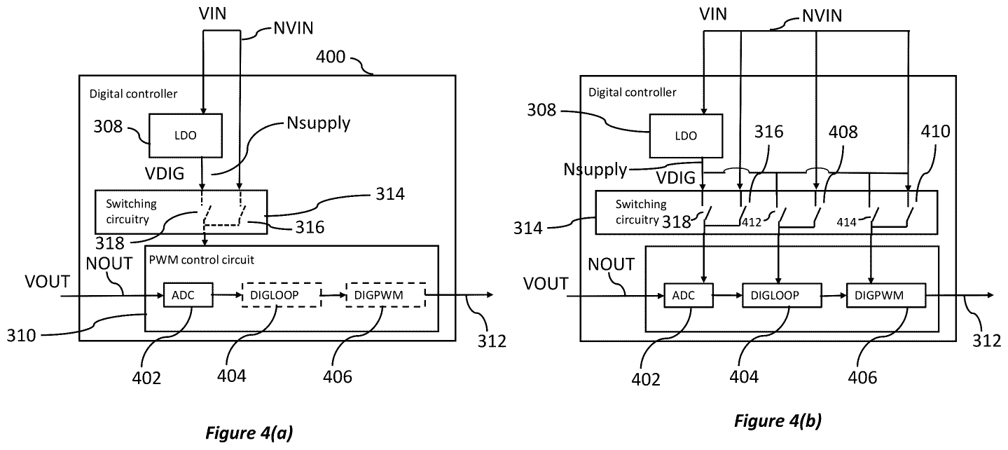

FIG. 4(a) is a schematic of a digital controller 400 in accordance with a second embodiment of the present disclosure. The digital controller 400 is a specific implementation of the digital controller 300.

In the present embodiment, the PWM control circuit 310 comprises an analog to digital converter (ADC) 402 coupled to the output voltage node NOUT and configured to digitize the output voltage VOUT.

The PWM control circuit 310 may further comprise a digital loop circuit 404.

The PWM control circuit 310 may further comprise a digital PWM circuit 406.

FIG. 4(b) is a schematic of the digital controller 400 of FIG. 4(a), with a specific embodiment of the switching circuitry 314, in accordance with a third embodiment of the present disclosure.

The first phase switches comprise the first switch 316, a third switch 408 and a fifth switch 410 for coupling the ADC 402, the digital loop circuit 404 and the digital PWM circuit 406, respectively, to the input voltage node NVIN during the first phase.

The second phase switches comprise the second switch 318, a fourth switch 412 and a sixth switch 414 for coupling the ADC 402, the digital loop circuit 404 and the digital PWM circuit 406, respectively, to the supply voltage node Nsupply during the second phase.

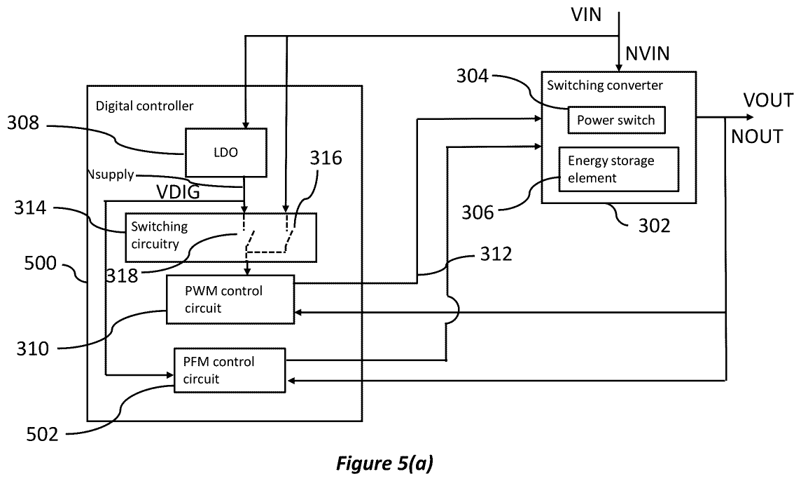

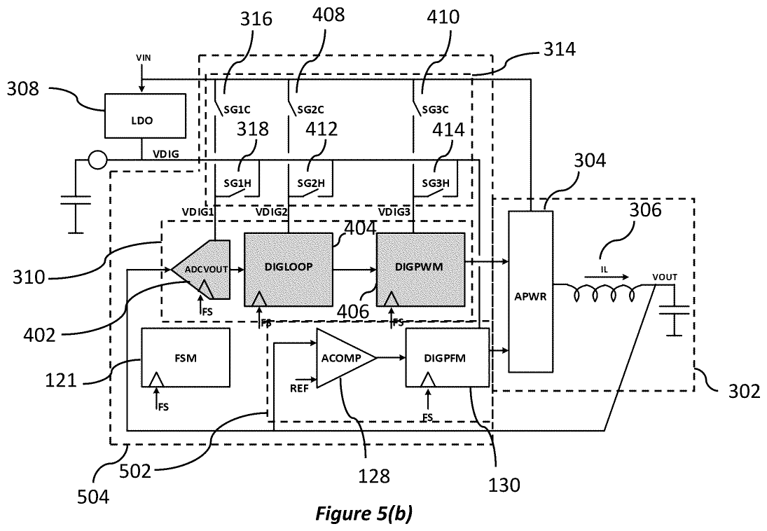

FIG. 5(a) is a schematic of a digital controller 500 and the switching converter 302, in accordance with a fourth embodiment of the present disclosure. The digital controller 500 may include any of features described in relation to other embodiments herein, and in accordance with the understanding of the skilled person.

In the present embodiment, the PWM control circuit 310 is configured to control the switching operation of the one or more power switches 304 during a first mode of operation. The first mode of operation may, for example, be used when there are “high load” requirements where the load current exceeds a threshold value.

The digital controller 500 may comprise additional circuitry 502 configured to control the switching operation of the one or more power switches 304 during a second mode of operation. The second mode of operation may, for example, be used when there are “light load” requirements, where the load current is below a threshold value. The additional circuitry may, for example, comprise a PFM control circuit.

FIG. 5(b) is a schematic of a digital controller 504 and the switching converter, in accordance with a fifth embodiment of the present disclosure. In the present example, the digital controller 504 shares features with the system as described in FIG. 2.

Embodiments of the digital controller as described herein provides the following advantages:
It suppresses the bounce/kick-back on VDIG that was due to the excessive in-rush (for example as would occur in the system of FIG. 2).
It allows shorter power-up times, typically 20 ns instead of 100 ns, and thus makes the full system compatible with BUCK PFM-to-PWM transition times.
It off-loads the top-cell routing, which can be constrained back to normal supply current IDD consumption, instead of having to cope with in-rush too.

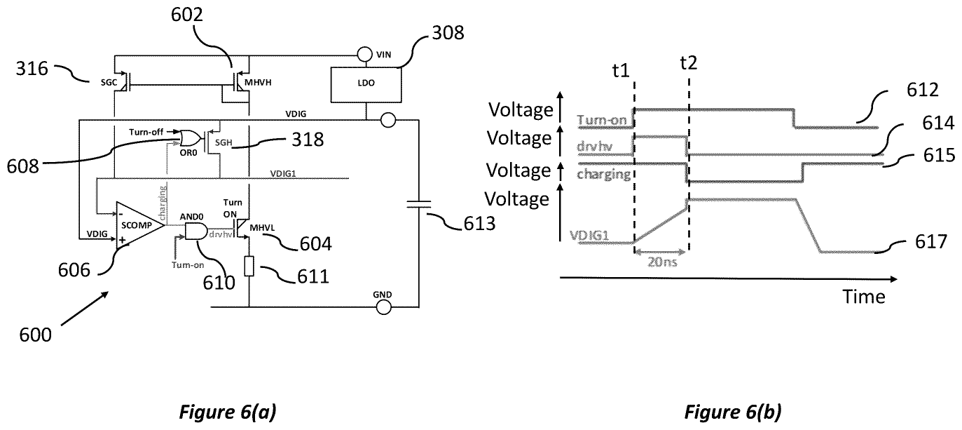

FIG. 6(a) is a schematic of a portion of a digital controller 600 as may be implemented in a specific embodiment of one of the digital controllers as described herein, in accordance with the understanding of the skilled person.

The present embodiment illustrates an example of how the switches 316, 318 may be operated based on the operational phase during the PWM mode of operation. Although illustrated for switches 316, 318, which are used for powering the ADC 402, it will be appreciated that the system of FIG. 6(b) may be applied alternatively, or additionally, to control the supply of power to the digital loop circuit 404 and/or the digital PWM circuit 406, in accordance with the understanding of the skilled person.

The switches 316, 318 each comprise a transistor. The digital controller 600 comprises a transistor 602 having a gate coupled to a gate of the transistor 316. The digital controller 600 further comprises a transistor 604 coupled in series with the transistor 602.

The digital controller 600 further comprises a comparator 606 having a first input coupled to the transistors 316, 318 and a second input coupled to the supply voltage node Nsupply. During operation, the comparator 606 outputs a charging signal (labelled “charging”).

The digital controller 600 further comprises an OR gate 608 comprising a first input terminal for receiving a turn-off signal, and a second input terminal for receiving the charging signal. The OR gate 608 has an output terminal coupled to a gate of the transistor 318.

The digital controller 600 further comprises an AND gate 610 having a first input for receiving the charging signal, and a second input terminal for receiving a turn-on signal. An output terminal of the AND gate 610 is coupled to a gate of the transistor 604.

The digital controller 600 further comprises a resistor 611 and a capacitor 613,

FIG. 6(b) is a graph showing example waveforms as they vary with time for a practical implementation of the digital controller 600 of FIG. 6(a). There is shown: a trace 612 of the turn-on signal; a trace 614 of the AND gate output signal; a trace 615 of the charging signal; and a trace 617 of the voltage on the voltage rail VDIG1 supplied to the ADC 402 during operation.

As discussed previously, three instances of the portion of the digital controller 600 may be used to control the power supply to each of the ADC 402, the digital loop circuit 404 and the digital PWM circuit 406, with a single instance being used for each of the three components. Such an embodiment would enable all the rails VDIG1, VDIG2, VIDG3 to simultaneously “wake up”.

Each rail VDIG1, VDIG2, VDIG3, is individually charged through its associated switch (316, 408, 410) with large in-rush current being provided straight from the input voltage VIN, thereby leaving the supply voltage VDIG unloaded.

Once these rails VDIG1, VDIG2, VDIG3 reach a voltage close to VDIG, the switches 316, 408, 410 may be turned off and the switches 318, 412, 414 may be turned ON, to connect each of VDIG1, VDIG2 and VDIG3 to VDIG. The normal operation is then resumed.

The lines connecting the switches 316, 408, 410 to VDIG1, VDIG2, VDIG3, respectively, are the only ones that must support the in-rush current, while the switches 318, 412, 414 may be lower voltage switches that are sized just for the current in normal operation.

With reference to FIG. 6(b), before a time t1, VDIG1 is disconnected from source of power, and the turn on signal is equal to zero. The transistor 604 is in an off state and therefore does not permit current flow, which deactivates the current mirror formed by the transistor 316 and the transistor 602. Also, the turn off signal is equal to one such that the transistor 602 is off. VDIG1 is in a high impedance state and may optionally be pulled down. In this case, VDIG1 becomes smaller than VDIG, in which case the charging signal is equal to one.

It will be appreciated that the comparator 606 may be a static comparator, such that it only consumes current when it is switching, otherwise it does not consume current.

When the FSM 121 sets the turn on signal to one at the time t1 and the turn off signal to zero, the output of the AND gate 610 goes to one and turns on the high voltage current mirror formed by the transistor 316 and the transistor 602. This mirror will charge VDIG1 from the input voltage VIN.

In a specific example, the FSM 121 requires information of when to enable the buck converter. This could be indicated, for example, from a central point in the system or an external host. The FSM 121 itself will follow a pre-defined (or configurable) order of transitions for start-up and shut-down.

In summary: the FSM 121 monitors the load and transitions into PWM for high loads (Turn-on asserted and Turn-off de-asserted) and PFM for low loads (Turn-on de-asserted and turn-off asserted).

When VDIG1 exceeds VDIG, the comparator 606 sets the charging signal to zero, at a time t2. This resets the output of the AND gate 610 to zero and stops the high-voltage current mirror from charging VDIG1, which turns on the transistor 318 to connect and hold VDIG1 to the supply voltage VDIG.

Tin summary, the rail VDIG1 now has two switches for power-gating:
The switch 316 (Charging Switch): it has high-voltage properties to charge VDIG1 from VIN
The switch 318 (Holding Switch): it is a low-voltage switch to hold VDIG1 to VDIG.

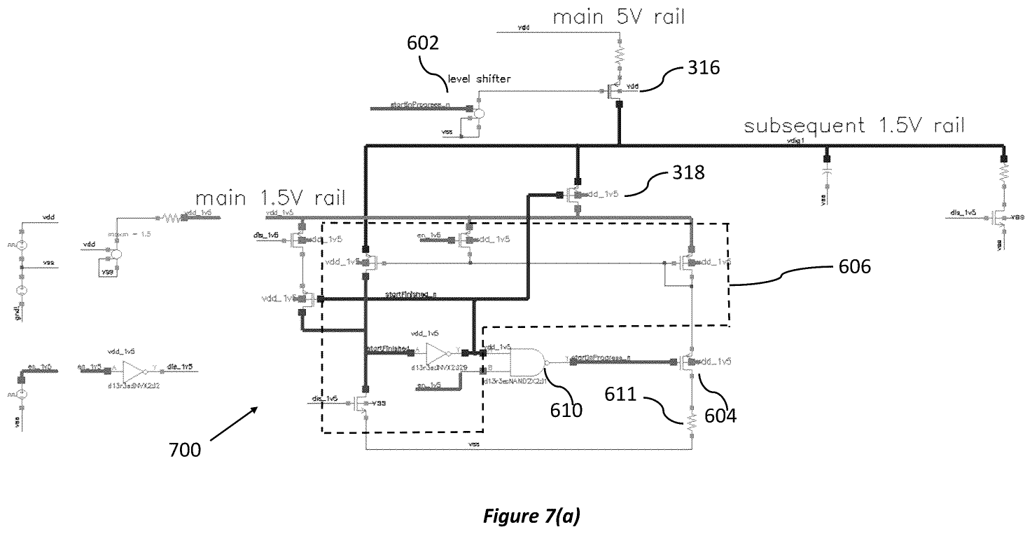

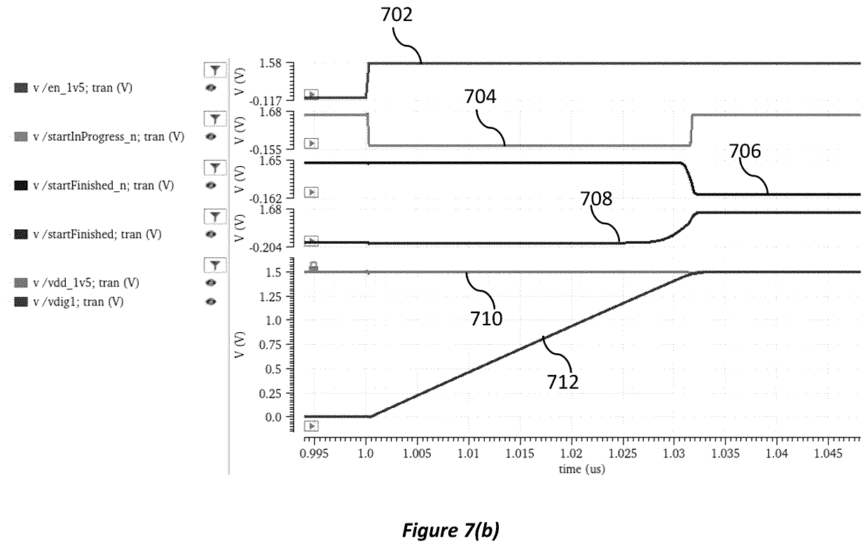

FIG. 7(a) is a schematic of a digital controller 700 in accordance with a sixth embodiment of the present disclosure.

The present embodiment shows a possible implementation with a common gate style amplifier. The present embodiment does not use a current mirror so the charging current is defined by the top resistor and the current can vary with the voltage vdd.

FIG. 7(b) is a graph showing simulation results of the system presented in FIG. 7(a) and using parameters that are suitable for a practical implementation.

A trace 702 is a turn on signal; a trace 704 shows a start in progress signal; a trace 706 shows a first start finished signal; a trace 708 shows a second start finish signal; a trace 710 shows VDIG (as shown in FIG. 5(b)); and a trace 712 shows VDIG1 (as shown in FIG. 5(b)). It should be noted that *_n indicates the traces startInProgress_n and startFinished_n are “inverted” in relation to the behaviour the name would suggest (these signal are effectively active low).

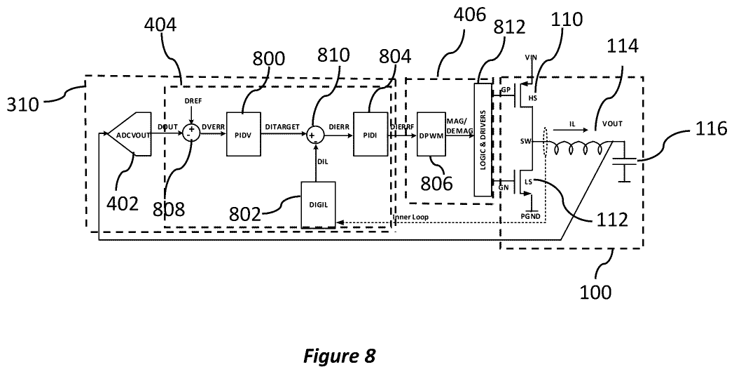

FIG. 8 is a schematic of a specific embodiment of the PWM control circuit 310, one or more features of which may be implemented in the embodiments of the present disclosure, in accordance with the understanding of the skilled person.

Operation of the circuit of FIG. 8 is as follows:
The output voltage VOUT is digitized through the ADC 402 to give a digitized output voltage signal DOUT. The digitized output voltage signal DOUT is compared to a digital reference voltage DREF that corresponds to the target voltage for the output voltage VOUT. Both numbers DOUT, DREF can be e.g. 8-bit bus, where the digital code [0; 255] corresponds to the analog range [0.50V; 1.50V].
A digital error voltage signal DVERR is equal to DREF-DOUT, which is provided into a digital loop control proportional-integral-derivative (PID) circuit 800 to convert this digitized error voltage DVERR into a digital target current DITARGET, which is a digital number that is the target to set for the analog inductor current IL. Thus, if the output voltage VOUT decreases, then the digitized output voltage signal DOUT decreases, the digital error voltage signal DVERR increases and the digital target current DITARGET increases: the digital control PID 800 requests more inductor current IL to restore the output voltage VOUT.
The digital target current DITARGET may be coded on more bits, e.g. 16 bits, as well as the following signals. The inductor target current DITARGET enters an “inner loop” made of (a digital current generation circuit 802; a PIDI circuit 804; a PWM circuit 806 and the power-stage 100). This inner loop adjusts the duty-cycle MAG/DEMAG such that the analog inductor current IL matches its digital counterpart inductor current target DITARGET on average.
The digital current generation circuit 802 may be the ADC 104 as shown in FIG. 1(a) or may be a “synthesizer”, so it can reproduce, in digital, the inductor current IL-behavior depending on the input voltage VIN, the output voltage VOUT, the duty-cycle and possibly other parameters.
The inner loop operates as follows: if the digital target current DITARGET is higher than the digital inductor current DIL, the digital current error DIERR increases. The digital current error DIERR passes through an integrator (PID 804) to generate a filtered and amplified version, being the filtered digital current error DIERRF which increases and enters a Digital-to-Duty converter (the PWM circuit 806) to increase the duty-cycle. This results in an increase in the inductor current IL.

The digital loop circuit 404 also comprises addition/subtraction circuits 808, 810 and the digital PWM circuit 406 comprises the logic and gate driver circuit 812.

Once the inner loop has settled to a steady state, the average digital target current is equal to the average digital inductor current, which may be denoted as follows:

$$< DITARGET >= < DIL > \qquad ( 3 )$$

A variable enclosed by “< >” is used to denote an average of the variable. For example, <x> denotes the average of the variable x.

In summary, embodiments of the present disclosure use power-gating introduced in time-critical control loops of DC-DC converters to make it possible to use lower supply/lower latency/higher leakage voltage technology. This is desirable because of the time critical nature of the control loop's regulation of VOUT, and intense processing and computations have to be completed within two clock cycles (i.e. 40 ns for a 50 MHz clock) as well to achieve the required timing. Furthermore, embodiments of the present disclosure may use dual switch charging/holding power-gating to accommodate the needs for a buck converter (leakage and 20 ns transition time) and the needs for the PMIC top-cell (routing and kick-back/in-rush on VDIG).

Embodiments of the present disclosure can reduce the power consumption and improve the efficiency of a controller for a switching converter that uses a pulse width modulation control scheme, when compared with known systems. Furthermore, embodiments of the present disclosure can meet power-up timing criteria that are not met by known systems.

Various improvements and modifications may be made to the above without departing from the scope of the disclosure.

1. A digital controller for a switching converter configured to receive an input voltage at an input voltage node and to generate an output voltage at an output voltage node, the switching converter comprising one or more power switches and an energy storage element, the digital controller comprising:
a pulse width modulation control circuit configured to receive the output voltage and to generate a PWM control signal to control the switching operation of the one or more power switches; and
switching circuitry configured to:
i) couple the pulse width modulation control circuit to the input voltage node during a first phase; and
ii) couple the pulse width modulation control circuit to a supply voltage node during a second phase, the supply voltage node being at a supply voltage.

2. The digital controller of claim 1, wherein the switching converter is a buck converter, a boost converter, or a buck-boost converter.

3. The digital controller of claim 1, wherein the energy storage element is an inductor.

4. The digital controller of claim 1, wherein the pulse width modulation control circuit comprises an analog to digital converter coupled to the output voltage node and configured to digitize the output voltage to provide a digital representation of the output voltage.

5. The digital controller of claim 4, wherein the pulse width modulation control circuit comprises a digital loop circuit.

6. The digital controller of claim 5, wherein the pulse width modulation control circuit comprises a digital PWM circuit.

7. The digital controller of claim 1, wherein the first phase precedes the second phase.

8. The digital controller of claim 7, wherein the first phase is a charging phase and the second phase is a holding phase.

9. The digital controller of claim 1, wherein during the first phase, the supply voltage node is decoupled from the pulse width modulation control circuit and during the second phase the input voltage node is decoupled from the pulse width modulation control circuit.

10. The digital controller of claim 1, wherein the switching circuitry comprises one or more first phase switches for coupling the pulse width modulation control circuit to the input voltage node during the first phase and one or more second phase switches for coupling the pulse width modulation control circuit to the supply voltage node during the second phase.

11. The digital controller of claim 10, wherein during the first phase, the one or more second phase switches are open such that the supply voltage node is decoupled from the pulse width modulation control circuit and during the second phase, the one or more first phase switches are open such that the input voltage node is decoupled from the pulse width modulation control circuit.

12. The digital controller of claim 10, wherein:
the pulse width modulation control circuit comprises an analog to digital converter coupled to the output voltage node and configured to digitize the output voltage to provide a digital representation of the output voltage;
the one or more first phase switches comprises a first switch for coupling the analog to digital converter to the input voltage node during the first phase; and
the one or more second phase switches comprises a second switch for coupling the analog to digital converter to the supply voltage node during the second phase.

13. The digital controller of claim 12, wherein:
the pulse width modulation control circuit comprises a digital loop circuit;
the one or more first phase switches comprises a third switch for coupling the digital loop circuit to the input voltage node during the first phase; and
the one or more second phase switches comprises a fourth switch for coupling the digital loop circuit to the supply voltage node during the second phase.

14. The digital controller of claim 1, wherein the pulse width modulation control circuit is configured to control the switching operation of the one or more switches during a first mode of operation.

15. The digital controller of claim 14, comprising additional control circuitry configured to control the switching operation of the one or more switches during a second mode of operation.

16. The digital controller of claim 15, wherein the additional control circuitry comprises a pulse frequency modulation control circuit.

17. The digital controller of claim 1 comprising a voltage regulator or a power rail for providing the supply voltage at the supply voltage node.

18. The digital controller of claim 17, wherein the voltage regulator comprises a low dropout regulator or a buck converter.

19. The digital controller of claim 17, wherein the voltage regulator comprises a low dropout regulator configured to receive the input voltage and to provide the supply voltage at the supply voltage node.

20. A method of controlling a switching converter configured to receive an input voltage at an input voltage node and to generate an output voltage at an output voltage node, the switching converter comprising one or more power switches and an energy storage element, the method comprising:
receiving the output voltage at a pulse width modulation control circuit;
generating a PWM control signal to control the switching operation of the one or more power switches using the pulse width modulation control circuit;
coupling the pulse width modulation control circuit to the input voltage node during a first phase; and
coupling the pulse width modulation control circuit to a supply voltage node during a second phase, the supply voltage node being at a supply voltage.
